(19) United States
(12) Patent Application Publication
(10) Pub. No.: US 2010/0279491 A1
(43) Pub. Date: Nov. 4, 2010

(54) DIE ATTACH FILM-PROVIDED DICING TAPE AND PRODUCTION PROCESS OF SEMICONDUCTOR DEVICE

(75) Inventors: Kazuyuki KIUCHI, Osaka (JP); Akinori NISHIO, Osaka (JP)

Correspondence Address: SUGHRUE-265550, 2100 PENNSYLVANIA AVE. NW, WASHINGTON, DC, 20037-3213, US

(73) Assignee: NITTO DENKO CORPORATION, Ibaraki-shi (JP)

(21) Appl. No.: 12/769,959

(22) Filed: Apr. 29, 2010

(30) Foreign Application Priority Data
May 1, 2009 (JP) 2009-112002

(51) Int. Cl. H01L 21/78; B32B 7/12

(52) U.S. Cl. 438/464; 428/354; 428/345; 257/E21.599

(57) ABSTRACT

The present invention provides a die attach film-provided dicing tape, which includes a dicing tape, a supporting tape and a die attach film laminated in this order, wherein the supporting tape is a tape having a self-rolling peelability, and a process for producing a semiconductor device by using the die attach film-provided dicing tape.

### FIELD OF THE INVENTION

The present invention relates to a die attach film-provided dicing tape, which is used in a series of steps from a dicing step to a die bonding step of a semiconductor wafer, and a process for producing a semiconductor device by using the die attach film-provided dicing tape.

### BACKGROUND OF THE INVENTION

A semiconductor device is generally fabricated through a process of forming a circuit pattern or the like on a semiconductor wafer, polishing the back surface of the wafer, dicing the wafer in a state of being fixed with a dicing tape, thereby dividing the wafer into chips, picking up the obtained semiconductor chip, and bonding it to a die pad part.

The picking after dividing a semiconductor wafer into chips is performed using various methods, for example, by a method of pushing up a chip with a needle (needle pickup method) or a needle-less method of vacuum suctioning a dicing tape. However, thinning of a semiconductor chip in recent years makes it difficult to efficiently pick up a chip without a damage. In the needle pickup method, with the progress in optimization of an apparatus in terms of needle pin tip shape, pin array, adsorption collet shape and the like and in optimization of the adhesive strength, stretchability of backing material, and the like of a dicing tape, picking is possible up to a chip thickness of about 50 μm.

On the other hand, a silver paste agent has been heretofore used as an adhesive when fixing a chip to a lead frame, an interposer or the like in a die bonding step, but uniform coating of the adhesive is difficult and a silver paste agent protruded from the outer periphery of a chip may incur a short circuit. For this reason, a die attach film is increasingly used in place of a silver paste agent. For example, in a stack package or the like of a flash memory, it becomes predominant to use a die attach film-provided dicing tape, where a dicing tape for fixing a wafer in the dicing step and a die attach film for adhering a chip to a die pad part in the die bonding step are combined. Meanwhile, studies to reduce the chip thickness to 50 μm or less are proceeding.

However, when the chip thickness is reduced to 50 μm or less, the chip is significantly decreased in the rigidity and becomes highly flexible and therefore, there arises a case where even when a chip is pushed up by a needle, the chip possessing a die attach film bows following the deformation of a dicing tape and cannot be picked up by an adsorption collet. In a severe case, the chip may be damaged by the needle pushing.

Also, in the needle-less system, balance setting between the vacuum adsorption force for a chip by an adsorption collet and the vacuum suctioning force for a dicing tape is difficult and similarly to the needle pickup method, this system has a risk of pickup failure or chip damage. Optimization of the pickup conditions requires tremendous efforts.

JP-A-2003-332267 (the term “JP-A” as used herein means an “unexamined published Japanese patent application”) describes a method for reducing damage to a thin wafer during processing and transfer, where the processing and transfer are performed in a state of a semiconductor wafer/a reinforcing sheet/a dicing tape being laminated together in this order. However, in this method, the backing material of the reinforcing sheet is separated when picking up a chip after dividing the semiconductor wafer into chips and therefore, an ultrathin semiconductor chip is likely to encounter pickup failure or damage.

### SUMMARY OF THE INVENTION

An object of the present invention is to provide a die attach film-provided dicing tape, ensuring that even an ultrathin semiconductor chip having as small a thickness as 50 μm or less can be smoothly picked up at a high rate of success and moreover, that the mounting efficiency in die attaching is not reduced and a semiconductor device can be produced with high productivity.

Another object of the present invention is to provide a process for producing a semiconductor device using the above-described die attach film-provided dicing tape.

As a result of intensive studies to attain these objects, the present inventors have found that in the case of an ultrathin chip, bowing of a chip at the picking is the main cause of inhibiting separation from a dicing tape, bringing about pickup failure or chip damage, and reducing the rate of success of picking; and that when a supporting tape having a self-rolling peelability is allowed to intervene between the dicing tape and the die attach film, rigidity is imparted, the chip can be prevented from bowing at the picking and smoothly picked up from the dicing tape surface, and since the supporting tape which is no longer required after the picking can be easily removed by self-rolling separation without damaging the chip, the mounting efficiency in die attaching is not reduced. The present invention has been accomplished based on this findings.

That is, the present invention provides a die attach film-provided dicing tape, which comprises a dicing tape, a supporting tape and a die attach film laminated in this order, wherein the supporting tape is a tape having a self-rolling peelability.

In the above-mentioned die attach film-provided dicing tape, it is preferable that the dicing tape and the supporting tape are separable from each other at a picking after a dicing of an adherend.

The supporting tape may includes a heat contractible backing layer, an elastic layer and a rigid backing layer laminated in this order from the dicing tape side, or includes a heat contractible backing layer, an elastic layer, a rigid backing layer and a pressure-sensitive adhesive layer (A) laminated in this order from the dicing tape side. The pressure-sensitive adhesive layer (A) may be constituted of a pressure-sensitive adhesive or an active energy ray-curable pressure-sensitive adhesive.

The dicing tape may includes a pressure-sensitive adhesive layer (B) and a backing layer laminated in this order from the supporting tape side. The pressure-sensitive adhesive layer (B) may be constituted of a pressure-sensitive adhesive or an active energy ray-curable pressure-sensitive adhesive.

The die attach film may be constituted of a resin composition containing an epoxy resin.

The present invention also provides a process for producing a semiconductor device, which comprises: laminating a semiconductor wafer to a die attach film surface of the above-mentioned die attach film-provided dicing tape to form a laminate structure comprising the dicing tape, the supporting tape, the die attach film and the semiconductor wafer laminated in this order; and dicing the resulting laminate structure from the wafer side, followed by pushing it from the dicing tape side, thereby collecting a semiconductor chip possessing the supporting tape and the die attach film.

The above-mentioned process for producing a semiconductor device may further includes allowing the supporting tape to undergo self-rolling separation from the collected semiconductor chip possessing the supporting tape and the die attach film, thereby obtaining the semiconductor chip possessing the die attach film.

In the above-mentioned process for producing a semiconductor device, the semiconductor chip possessing the die attach film may be obtained by collecting the semiconductor chip possessing the supporting tape and the die attach film by the use of a pickup adsorption collet equipped with a heating mechanism, followed by heating the supporting tape to undergo self-rolling separation from the collected semiconductor chip possessing the supporting tape and the die attach film.

The above-mentioned process for producing a semiconductor device may further includes bonding the obtained semiconductor chip possessing the die attach film to a die pad part.

The die attach film-provided dicing tape of the present invention has a construction where a dicing tape and a die attach film are laminated together, so that a semiconductor device can be efficiently produced by a coherent process from dicing to die bonding. Also, a dicing tape and a die attach film are stacked through a supporting tape having a self-rolling peelability and in turn, even an ultrathin chip having a bowing propensity is imparted with rigidity by the supporting tape, so that pickup failure or chip damage due to bowing (deflection) of a chip can be prevented and smooth picking can be easily performed. Furthermore, the supporting tape which is no longer required after the picking can be easily removed by self-rolling separation until die bonding and therefore, the mounting efficiency in the die bonding step is not reduced. As a result, a semiconductor device using an ultrathin chip can be produced with high productivity.

### BRIEF DESCRIPTION OF THE DRAWINGS

FIG. 1 is a schematic cross-sectional view showing one example of the die attach film-provided dicing tape of the present invention.

FIGS. 2A to 2C are views (perspective views) showing how the supporting tape of the die attach film-provided dicing tape of the present invention undergoes self-rolling (spontaneous rolling).

FIG. 3 is a schematic view (cross-sectional view) showing one example of the production process of a semiconductor device of the present invention.

### DESCRIPTION OF REFERENCE NUMERALS AND SIGNS

1 Dicing tape
11 Backing layer
12 Pressure-sensitive adhesive layer (B)
2 Supporting tape
21 Heat contractible backing layer
22 Elastic layer
23 Rigid backing layer
24 Pressure-sensitive adhesive layer (A)
3 Die attach film
4 Die attach film-provided dicing tape
5 Semiconductor wafer
6 Dicer
7 Chip
8 Pickup needle
9 Heater collet
10 Die pad part
20 Cylindrical roll

### DETAILED DESCRIPTION OF THE INVENTION

The mode for carrying out the present invention is described in detail below by referring to the drawings, if desired.

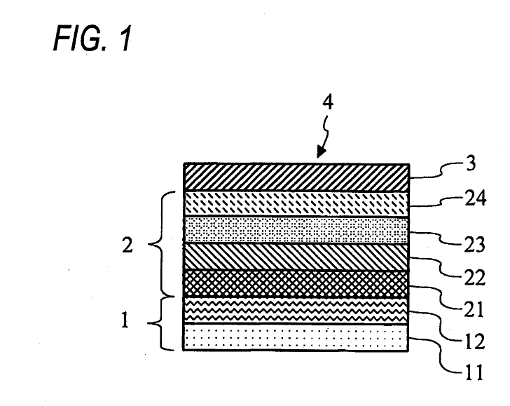

FIG. 1 is a schematic cross-sectional view showing one example of the die attach film-provided dicing tape of the present invention. In the die attach film-provided dicing tape 4 of this example, a dicing tape 1, a supporting tape 2 and a die attach film 3 are laminated in this order. The supporting tape 2 has a layer construction of, in order from the dicing tape 1 side, a heat contractible backing layer 21/an elastic layer 22/a rigid backing layer 23/a pressure-sensitive adhesive layer (A) 24. Further, the dicing tape 1 has a layer construction of a pressure-sensitive adhesive layer (B) 12/a backing layer 11 in order from the supporting tape side 2.

### Dicing Tape

In the present invention, as for the dicing tape, a known dicing tape used for temporarily fixing an adherend (material to be processed) such as semiconductor wafer when dicing the adherend (material to be processed) can be used.

The backing layer 11 of the dicing tape 1 is preferably a plastic film (plastic backing material), and examples of the material of the backing layer 11 include an olefin-based resin using an α-olefin as a monomer component, such as polyethylene (PE), polypropylene (PP), polymethylpentene (PMP), ethylene-propylene copolymer and ethylene-vinyl acetate copolymer (EVA); a polyester-based resin such as polyethylene terephthalate (PET), polyethylene naphthalate (PEN) and polybutylene terephthalate (PBT); and a polyvinyl chloride (PVC). One of these materials may be used alone, or two or more thereof may be used in combination. Above all, in view of stretchability of the backing material at the picking, an olefin-based resin, PVC and the like are preferred.

The pressure-sensitive adhesive constituting the pressure-sensitive adhesive layer (B) 12 is preferably a pressure-sensitive adhesive (non-active energy ray-curable pressure-sensitive adhesive) or an active energy ray-curable pressure-sensitive adhesive, and the same as those exemplified later for the pressure-sensitive adhesive layer (A) 24 of the supporting tape 2 can be used.

The adhesive strength of the pressure-sensitive adhesive layer (B) 12 at the picking (the adhesive strength (180° peeling, vs. silicon mirror wafer, tensile rate: 300 mm/min) of the pressure-sensitive adhesive layer or pressure-sensitive adhesive layer after an adhesion reducing treatment) is, for example, approximately from 0.01 to 1 N/10 mm, preferably on the order of 0.01 to 0.5 N/10 mm, at room temperature (25° C.).

Examples of the dicing tape 1 which can be used include a commercially available dicing tape such as “DU-300” and “V-8-S” (trade names, produced by Nitto Denko Corp.).

### Supporting Tape

In the present invention, a tape (sheet) having a self-rolling peelability is used as the supporting tape. The term “self-rolling peelability” indicates a property of being peelable from a material to be supported (die attach film 3) upon application of a stimulus such as heat while self-rolling to form a roll without requiring any particular external force thereafter. Examples of the stimulus for promoting rolling of the supporting tape include heat, light and electricity, with heat being preferred. Also, the supporting tape is preferably a contractible backing material that contracts due to a stimulus such as heat. Incidentally, the supporting tape preferably rolls up by a stimulus such as heat to form a cylindrical roll that is completely rolled with both edges being overlapped, but may not roll up into a complete cylinder and form a (gutter) shape where both edges are not overlapped and a part of the side surface of the cylinder is opened in the longitudinal direction.

In the example above, other than the above-described layer construction of a heat contractible backing layer 21/an elastic layer 22/a rigid backing layer 23/a pressure-sensitive adhesive layer (A) 24, for example, in the case where the die attach film 3 itself has self-adhesiveness, the supporting tape 2 may be a tape (sheet) having a layer construction of a heat contractible backing layer 21/an elastic layer 22/a rigid backing layer 23 in order from the dicing tape 1 side.

### (Heat Contractible Backing Layer)

The heat contractive backing layer 21 may be sufficient if it is a film layer capable of exerting contractibility under heating, and may be any of a uniaxially contractible film, a biaxially contractible film and the like. As for the uniaxially contractible film, a uniaxially contractible film having contractibility only in one direction may be used, or a contractible film having main contractility in a certain direction (one direction) and having secondary contractibility in a different direction (for example, a direction perpendicular to the direction above) may be used. Also, the heat contractible backing layer 21 may be a single layer or a multilayer composed of two or more layers.

The contraction percentage in the main contraction direction of the contractible film constituting the heat contractible backing layer 21 is preferably from 30 to 90%, more preferably from 50 to 90%, at a predetermined temperature (for example, 80° C.) in the range of from 60 to 180° C. Incidentally, in the case where the film contracts biaxially at a predetermined temperature (for example, 80° C.) in the range of from 60 to 180° C., the axial direction having a higher contraction percentage is taken as the main contraction direction. Heat contractibility of the contractible film can be imparted, for example, by subjecting a film extruded by an extruder to a stretching treatment in a uniaxial direction or a biaxial direction, and the contraction percentage can be adjusted by the degree of stretching.

As for the uniaxially contractible film, a contractible film in which the contraction percentage in the direction other than the main contraction direction is less than 10% (preferably 5% or less, more preferably 3% or less) can be used. In the case of a uniaxially contractible film, when a thermal stimulus is applied, as described later, repulsion for contraction force of the heat contractible backing layer 21, which occurs in the restriction layer (elastic layer 22+rigid backing layer 23), becomes a driving force for causing the supporting tape 2 to lift at its outer edge (one end part or two opposing end parts), undergo self-rolling from the end part in one direction or toward central direction (usually, in the main contraction axis direction of the heat contractible backing layer 21), with the heat contractible backing layer 21 side inward, and separate from the die attach film 3.

As for the biaxially contractible film, a contractible film in which the contraction percentage in the direction other than the main contraction direction is 10% or more [for example, from 10 to 80%, preferably 15% or more (for example, from 15 to 80%)] can be used. The ratio (A:B) between the contraction percentage in the main contraction direction [A (%)] and the contraction percentage in the direction perpendicular to the main contraction direction [B (%)] is preferably from 1:1 to 10:1, more preferably from 1:1 to 5:1, still more preferably from 1:1 to 3:1. The biaxially contractible film not only contracts in the perpendicular two directions but also presumably allows contraction stresses created by two contraction axes to be synthesized and act and therefore, the heat contractible film can be contracted by heating it from any direction. The supporting tape 2 spontaneously warps, with the heat contractible backing layer 21 side inward, to form a lift between the tape and the adherend, spontaneously rolls up in one direction from one end part when further heated, and separates from the die attach film 3.

In the case where an active energy ray-curable pressure-sensitive adhesive layer is used as the elastic layer 22 connecting the heat contractible backing layer 21 to the rigid backing layer 23 and as the pressure-sensitive adhesive layer (A) 24 for the lamination with a die attach film 3 and at the same time, where an active energy ray is irradiated through the heat contractible backing layer 21, the heat contractible backing layer 21 must be formed of a material capable of passing an active energy ray in not less than a predetermined amount (for example, a resin having transparency).

As for the heat contractible film constituting the heat contractible backing layer 21, there may be suitably used, for example, a heat contractible film composed of one resin or two or more resins selected from polymers having ultraviolet transparency, such as polyolefins (e.g., polypropylene, polyethylene), polyesters (e.g., polyethylene terephthalate, polybutylene terephthalate, polylactic acid), polyimides (e.g., kapton); polyamides (e.g., 6,6-nylon), polyether sulfonic acids, polynorbornene, polyurethane, polystyrene and polyvinylidene chloride.

Above all, the heat contractible film is preferably a uniaxially or biaxially stretched film composed of a polyester-based resin, a polyolefin-based resin (including a cyclic polyolefin-based resin) such as polyethylene, polypropylene and polynorbornene, or a polyurethane-based resin. Such a film has advantages such as excellent workability in coating of the pressure-sensitive adhesive, good profitability such as cost, high pressure-sensitive adhesiveness to the elastic layer used for the lamination with the later-described rigid backing layer, and fast response to the contraction initiation temperature.

The thickness of the heat contractible backing layer 21 is generally from 5 to 300 μm, and in view of cuttability, preferably from 10 to 100 μm, more preferably from 10 to 60 μm. If the thickness of the heat contractible backing layer 21 is excessively large, this is not only unprofitable but also yields high rigidity and there is a tendency to disallow self-rolling or cause separation between the heat contractible layer 21 and the elastic layer 22, resulting in laminate fracture. On the other hand, if the thickness of the heat contractive backing layer 21 is too small, poor operability is incurred, for example, making it difficult to wind or feed the film at the production, and also the rigidity of the supporting tape 2 as a whole surpasses the contraction stress that is unduly diminished, as a result, self-rolling hardly occurs.

The surface of the heat contractible backing layer 21 may be subjected to a conventional release treatment (mold release treatment) or the like so as to enhance the peelability from the adjacent layer (dicing tape 1).

Examples of the uniaxially contractible film that can be used to form the heat contractible backing layer 21 in the present invention include commercial products available under the trade name of “SPACECLEAN” (produced by Toyobo Co., Ltd.), the trade name of “Lumirror” (produced by Toray Industries, Inc.), the trade name of “ARTON” (produced by JSR Corp.), the trade name of “ZEONOR” (produced by ZEON Corp.), and the trade name of “SUNTEC” (produced by Asahi Chemical Industry Co., Ltd.). Examples of the biaxially contractible film that can be used to form the heat contractible backing layer 21 include commercial products available under the trade name of “SPACECLEAN” (produced by Toyobo Co., Ltd.), the trade name of “FANCYWRAP” (produced by Gunze Ltd.), the trade name of “TORAYFAN” (produced by Toray Industries, Inc.), the trade name of “Lumirror” (produced by Toray Industries, Inc.), the trade name of “ARTON” (produced by JSR Corp.), the trade name of “ZEONOR” (produced by ZEON Corp.), the trade name of “SUNTEC” (produced by Asahi Chemical Industry Co., Ltd.), the trade name of “SOPRA” (produced by Sekisui Chemical Co., Ltd.), the trade name of “KOHJIN POLYSET” (produced by KOHJIN Co., Ltd.), and the trade name of “TERRAMAC” (produced by Unitika Ltd.). The commercial product above may be appropriately subjected to a stretching treatment or a crosslinking treatment, if desired, and the surface thereof may be subjected to a corona treatment or a print processing treatment. By applying a stretching treatment, higher contractibility can be imparted.

### (Elastic Layer)

In the present invention, the elastic layer 22 and the rigid backing layer 23 function as a restriction layer that restricts contraction of the heat contractible backing layer 21. This restriction layer restricts contraction of the heat contractible backing layer 21 to yield a reaction force, and the supporting tape 2 as a whole thereby produces a couple of force, which works out to a driving force of inducing rolling.

The elastic layer 22 is preferably deformable at the temperature on the contraction of the heat contractible backing layer 21, that is, preferably in a rubbery state. However, with a material having fluidity, a sufficient reaction force is not yielded, and the heat contractible backing layer 21 alone is finally caused to undergo contraction, failing in bringing about deformation (self-rolling). Accordingly, the elastic layer 22 is preferably a layer whose fluidity is suppressed by three-dimensional crosslinking or the like. Also, depending on the thickness, the elastic layer 22 has an action of standing against a weak force component out of non-uniform contraction forces of the heat contractible backing layer 21 and preventing the contraction deformation by the weaker force component, thereby converting the contraction to a uniform contraction direction.

Accordingly, the elastic layer 22 is preferably formed of a resin having pressure-sensitive adhesiveness and having a glass transition temperature of, for example, 50° C. or less, preferably room temperature (25° C.) or less, more preferably 0° C. or less. The adhesive strength of the elastic layer 22 surface on the heat contractible backing layer 21 side is preferably 0.5 N/10 mm or more as a value in a 180° peeling test (in accordance with JIS Z 0237, tensile rate: 300 mm/min, 50° C.). If this adhesive strength is too low, separation is liable to occur between the heat contractible backing layer 21 and the elastic layer 22.

The shear modulus G of the elastic layer 22 is from 1×10⁴ to 5×10⁶ Pa, preferably from 0.05×10⁶ to 3×10⁶ Pa, in a temperature range of from room temperature (25° C.) to a temperature on peeling (for example, 80° C.). If the shear modulus is too small, the action to convert a contraction stress of the heat contractible backing layer 21 into a stress necessary for rolling is insufficient, whereas if it is excessively large, rigidity is strengthened to impair the rolling property and additionally, an elastic layer having high elasticity generally lacks adhesive strength, making it difficult to produce a laminate, and also is poor in the action to relieve the residual stress.

The thickness of the elastic layer 22 can be arbitrarily selected within the range not impairing the cuttability or the function as a restriction layer but is usually 50 μm or less (for example, from 10 to 50 μm), preferably 35 μm or less (for example, from 10 to 35 μm), more preferably 20 μm or less (for example, from 10 to 20 μm). If the thickness is too small, a restriction property against contraction of the heat contractible backing layer 21 can be hardly obtained and the effect of relieving a stress also decreases, whereas if it is excessively large, the self-rolling property tends to be lowered, or cuttability, handleability and profitability are disadvantageously deteriorated.

Accordingly, the product of the shear modulus G (for example, the value at 80° C.) and the thickness of the elastic layer 22 (shear modulus G×thickness) is preferably from 1 to 250 N/m (more preferably from 1 to 150 N/m, still more preferably from 1.2 to 100 N/m).

Examples of the elastic layer 22 which can be used include a foam material (foamed film) whose surface (at least the surface on the heat contractible backing layer 21 side) is subjected to an adhesive treatment, such as urethane foam and acrylic foam, and a resin film (including a sheet) such as non-foamed resin film using rubber, thermoplastic elastomer or the like material.

The pressure-sensitive adhesive used in the adhesive treatment above is not particularly limited and, for example, one of known pressure-sensitive adhesives such as acrylic pressure-sensitive adhesive, rubber-based pressure-sensitive adhesive, vinyl alkyl ether-based pressure-sensitive adhesive, silicone-based pressure-sensitive adhesive, polyester-based pressure-sensitive adhesive, polyamide-based pressure-sensitive adhesive, urethane-based pressure-sensitive adhesive and styrene-diene block copolymer-based pressure-sensitive adhesive may be used, or two or more thereof may be used in combination. Above all, an acrylic pressure-sensitive adhesive is preferably used from the standpoint of adjusting the adhesive strength or the like. Incidentally, the resin of the pressure-sensitive adhesive used in the adhesive treatment and the resin of the foamed film or non-foamed resin film are preferably the same type of resins so as to obtain high affinity. For example, in the case of using an acrylic pressure-sensitive adhesive for the adhesive treatment, an acrylic foam or the like is suitable as the resin film.

Also, the elastic layer 22 may be formed of, for example, a resin composition having adhesiveness by itself, such as crosslinking acrylic pressure-sensitive adhesive and crosslinking polyester-based pressure-sensitive adhesive. Such a layer (pressure-sensitive adhesive layer) formed of a crosslinking acrylic pressure-sensitive adhesive, a crosslinking polyester-based pressure-sensitive adhesive or the like can be produced by a relatively simple and easy method without the need to separately apply an adhesive treatment and is preferably used because of its excellence in the productivity and profitability.

The crosslinking acrylic pressure-sensitive adhesive has a construction such that a crosslinking agent is added to an acrylic pressure-sensitive adhesive using an acrylic polymer as the base polymer. Examples of the acrylic polymer include a homo- or co-polymer of an alkyl (meth)acrylate such as C₁-C₂₀ alkyl (meth)acrylate, e.g., methyl (meth)acrylate, ethyl (meth)acrylate, butyl (meth)acrylate, 2-ethylhexyl (meth)acrylate, octyl (meth)acrylate; and a copolymer of an alkyl (meth)acrylate described above and other copolymerizable monomers [for example, a carboxyl group- or acid anhydride group-containing monomer such as acrylic acid, methacrylic acid, itaconic acid, fumaric acid and maleic anhydride; a hydroxyl group-containing monomer such as 2-hydroxyethyl (meth)acrylate; an amino group-containing monomer such as morpholyl (meth)acrylate; an amide group-containing monomer such as (meth)acrylamide; a cyano group-containing monomer such as (meth)acrylonitrile; and a (meth)acrylic acid ester having an alicyclic hydrocarbon group, such as isobornyl (meth)acrylate].

In particular, the acrylic polymer is preferably a copolymer of one kind or two or more kinds of C₁-C₁₂ alkyl (meth)acrylates (e.g., ethyl acrylate, butyl acrylate, 2-ethylhexyl acrylate) and at least one kind of a copolymerizable monomer selected from a hydroxyl group-containing monomer (e.g., 2-hydroxyethyl acrylate) and a carboxyl group- or acid anhydride group-containing monomer (e.g., acrylic acid), or a copolymer of one kind or two or more kinds of C₁-C₁₂ alkyl (meth)acrylates, an alicyclic hydrocarbon group-containing (meth)acrylic acid ester, and at least one kind of a copolymerizable monomer selected from a hydroxyl group-containing monomer and a carboxyl group- or acid anhydride group-containing monomer.

The acrylic polymer is prepared as a high-viscosity liquid prepolymer, for example, by polymerizing a monomer component exemplified above (and a polymerization initiator) with light (e.g., ultraviolet ray) in the absence of a solvent. A crosslinking agent is then added to this prepolymer, whereby a crosslinking acrylic pressure-sensitive adhesive composition can be obtained. Here, the crosslinking agent may be added at the production of the prepolymer. The crosslinking acrylic pressure-sensitive adhesive composition may also be obtained by adding a crosslinking agent and a solvent to an acrylic polymer obtained by the polymerization of a monomer component exemplified above or to a solution thereof (use of an acrylic polymer solution is not necessarily required).

The crosslinking agent is not particularly limited and, for example, an isocyanate-based crosslinking agent, a melamine-based crosslinking agent, an epoxy-based crosslinking agent, an acrylate-based crosslinking agent (polyfunctional acrylate), or a (meth)acrylic acid ester having an isocyanate group may be used. Examples of the acrylate-based crosslinking agent include hexanediol diacrylate, 1,4-butanediol diacrylate, trimethylolpropane triacrylate, pentaerythritol tetraacrylate and dipentaerythritol hexaacrylate. Examples of the (meth)acrylic acid ester having an isocyanate group include 2-isocyanatoethyl acrylate and 2-isocyanatoethyl methacrylate. Above all, the crosslinking agent is preferably an acrylate-based crosslinking agent (polyfunctional acrylate) or an ultraviolet ray (UV)-reactive crosslinking agent such as (meth)acrylic acid ester having an isocyanate group.

The amount of the crosslinking agent added is usually on the order of 0.01 to 150 parts by weight, preferably on the order of 0.05 to 50 parts by weight, more preferably on the order of 0.05 to 30 parts by weight, per 100 parts by weight of the base polymer.

The crosslinking acrylic pressure-sensitive adhesive may contain, in addition to the base polymer and the crosslinking agent, appropriate additives such as crosslinking accelerator, tackifier (e.g., rosin derivative resin, polyterpene resin, petroleum resin, oil-soluble phenol resin), thickener, plasticizer, filler, age resistor and antioxidant.

With respect to the crosslinked acrylic pressure-sensitive adhesive layer as the elastic layer 22, for example, a crosslinking acrylic pressure-sensitive adhesive composition prepared by adding a crosslinking agent to the above-described prepolymer is formed into a film shape having a desired thickness and a desired area by a known method such as casting method, and a crosslinking reaction (and polymerization of an unreacted monomer) is allowed to proceed by again irradiating light, whereby an elastic layer 22 appropriate to the purpose can be easily and simply obtained. The elastic layer (crosslinked acrylic pressure-sensitive adhesive layer) obtained in this way has self-adhesiveness and therefore, can be directly used by laminating it between the heat contractible backing layer 21 and the rigid backing layer 23. A double-sided adhesive tape commercially available, for example, under the trade name of “HJ-915 OW” produced by Nitto Denko Corporation can be used as the crosslinked acrylic pressure-sensitive adhesive layer. Incidentally, after laminating the film-shaped pressure-sensitive adhesive between the heat contractible backing layer 21 and the rigid backing layer 23, a crosslinking reaction may be performed by again irradiating light.

The crosslinked acrylic pressure-sensitive adhesive layer as the elastic layer 22 may also be obtained by coating a crosslinking acrylic pressure-sensitive adhesive composition containing a solvent having dissolved therein the above-described acrylic polymer and crosslinking agent on a surface of the rigid backing layer 23, laminating the heat contractible backing layer 21 thereon, and then irradiating light.

The crosslinking polyester-based pressure-sensitive adhesive has a construction such that a crosslinking agent is added to an polyester-based pressure-sensitive adhesive using an ester-based polymer as the base polymer. The ester-based polymer includes, for example, a polyester composed of a condensation polymerization product of a diol component and a dicarboxylic acid component.

Example of the diol component include a (poly)carbonate diol. Examples of the (poly)carbonate diol include a (poly)hexamethylene carbonate diol, a (poly)3-methyl(pentamethylene) carbonate diol, a (poly)trimethylene carbonate diol, and a copolymer thereof. Incidentally, when the (poly)carbonate diol is a polycarbonate diol, the polymerization degree thereof is not particularly limited.

Examples of the commercial product of the (poly)carbonate diol include those under the trade name of “PLACCEL CD208PL”, the trade name of “PLACCEL CD210PL”, the trade name of “PLACCEL CD220PL”, the trade name of “PLACCEL CD208”, the trade name of “PLACCEL CD210”, the trade name of “PLACCEL CD220”, the trade name of “PLACCEL CD208HL”, the trade name of “PLACCEL CD210HL”, and the trade name of “PLACCEL CD220HL” [all produced by Daicel Chemical Industries, Ltd.].

As for the diol component, in addition to the (poly)carbonate diol, a component such as ethylene glycol, propylene glycol, butanediol, hexanediol, octanediol, decanediol and octadecanediol may be used in combination, if desired. The diol components or (poly)carbonate diols can be used individually or in combination of two or more thereof.

The dicarboxylic acid component which can be suitably used is a dicarboxylic acid component containing, as the essential component, a dicarboxylic acid whose molecular skeleton is an aliphatic or alicyclic hydrocarbon group having a carbon number of 2 to 20, or a reactive derivative thereof. In the dicarboxylic acid whose molecular skeleton is an aliphatic or alicyclic hydrocarbon group having a carbon number of 2 to 20 or in the reactive derivative thereof, the hydrocarbon group may linear or branched. Typical examples of the dicarboxylic acid or a reactive derivative thereof include succinic acid, methylsuccinic acid, adipic acid, pimelic acid, azelaic acid, sebacic acid, 1,12-dodecanoic diacid, 1,14-tetradecanoic diacid, tetrahydrophthalic acid, endomethylene tetrahydrophthalic acid, and an acid anhydride or lower alkyl ester thereof. One of these dicarboxylic acid components may be used alone, or two or more thereof may be used in combination.

The combination of a diol component and a dicarboxylic acid component is preferably, for example, a combination of polycarbonate diol and sebacic anhydride, adipic acid, pimelic acid, suberic acid, azelaic acid, phthalic acid or maleic acid.

As for the crosslinking agent in the crosslinking polyester-based pressure-sensitive adhesive, the same as those described above for the crosslinking agent in the crosslinking acrylic pressure-sensitive adhesive can be used. The amount of the crosslinking agent added, the additives that may be added, and the method for forming the elastic layer are also the same as in the case of the crosslinking acrylic pressure-sensitive adhesive.

In the elastic layer 22 for use in the present invention, beads such as glass bead and resin bead may be further added as the constituting component. Addition of glass or resin beads to the elastic layer 22 is advantageous in that control of the pressure-sensitive adhesive property and the shear modulus is facilitated. The average particle diameter of the beads is, for example, from 1 to 100 μm, preferably on the order of 1 to 20 μm. The amount of the beads added is, for example, from 0.1 to 10 parts by weight, preferably from 1 to 4 parts by weight, per 100 parts by weight of the entire elastic layer 22. If the amount added is excessively large, the pressure-sensitive adhesive property may be deteriorated, whereas if it is too small, the above-described effect tends to be insufficient.

### (Rigid Backing Layer)

The rigid backing layer 23 has a function of imparting rigidity or toughness to the restriction layer (elastic layer 22+rigid backing layer 23), thereby yielding a reaction force for the contraction force of the heat contractible backing layer 21, and in turn, generating a couple of force necessary for rolling. By virtue of providing the rigid backing layer 23, when a heat stimulus is applied to the heat contractible backing layer 21, the supporting tape 2 smoothly undergoes self-rolling without stopping halfway or shifting the direction and can form a neatly shaped cylindrical roll. Also, rigidity is imparted to diced chips, and the picking can be smoothly performed while preventing damage to a chip.

The rigid film constituting the rigid backing layer 23 includes, for example, a film composed of one kind or two or more kinds of resins selected from a polyester such as polyethylene terephthalate, polybutylene terephthalate and polyethylene naphthalate; a polyolefin such as polyethylene and polypropylene; polyimide; polyamide; polyurethane; a styrene-based resin such as polystyrene; polyvinylidene chloride; and polyvinyl chloride. Above all, a polyester-based resin film, a polypropylene film, a polyamide film and the like are preferred in that, for example, the coating workability of a pressure-sensitive adhesive is excellent. In particular, a rigid backing layer composed of a polyethylene terephthalate is preferred because of its advantages such as good profitability in terms of cost or the like, high adherence to the elastic layer that is laminated with the heat contractible backing layer, excellent heat resistance and stability, and high mechanical strength. The rigid backing layer 23 may be either a single layer or a multilayer in which two or more layers are stacked.

The rigid film constituting the rigid backing layer 23 is preferably non-contractible and, for example, the heat contraction percentage at 80° C. is, for example, 5% or less, preferably 3% or less, more preferably 1% or less (still more preferably 0.5% or less). The rigid backing layer 23 may expand at the contraction of the heat contractible backing layer 21. That is, the heat contraction percentage of the rigid backing layer 23 may take a minus value. The lower limit of the heat contraction percentage of the rigid backing layer 23 is, for example, about −1%.

The product of the Young's modulus and the thickness (Young's modulus×thickness) of the rigid backing layer 23 is preferably 3.0×10⁵N/m or less (for example, from 1.0×10² to 3.0×10⁵N/m), more preferably 2.8×10⁵N/m or less (for example, from 1.0×10³ to 2.8×10⁵ N/m), at the temperature on separation (for example, 80° C.). If the product of the Young's modulus and the thickness of the rigid backing layer 23 is too small, the action to convert a contraction stress of the heat contractible backing layer 21 into a rolling stress is poor and the directional converging action is also likely to decrease, whereas if it is excessively large, rolling is liable to be suppressed by rigidity.

The Young's modulus of the rigid backing layer 23 is preferably from 3×10⁶ to 2×10¹⁰ N/m², more preferably from 1×10⁸ to 1×10¹⁰ N/m², at the temperature on separation (for example, 80° C.). If the Young's modulus is too small, a neatly shaped cylindrical roll is difficult to obtain, whereas if it is excessively large, the self-rolling can hardly occur.

The thickness of the rigid backing layer 23 can be selected by taking into consideration the cuttability and rigidity but is, for example, from 10 to 75 μm, preferably from 15 to 50 μm, more preferably from 20 to 40 μm. If the thickness is too small, a neatly shaped cylindrical roll is difficult to obtain, whereas if it is excessively large, the self-rolling property is decreased and the cuttability, handleability and profitability are disadvantageously deteriorated.

In the case where the pressure-sensitive adhesive layer (A) 24 is an energy ray-curable pressure-sensitive adhesive layer, the rigid backing layer 23 is preferably formed of a material suitable for letting an energy ray easily pass through, allows for arbitrary selection of the thickness in view of production, workability and the like, and has excellent formability for easy formation into a film shape.

Incidentally, in the case where the die attach film 3 has self-adhesiveness, the pressure-sensitive adhesive layer (A) 24 need not be provided as described above. In this case, when a rigid backing material subjected to a release treatment with silicone, fluorine-based resin, long-chain alkyl or the like is used for the rigid backing layer 23 on the side laminated with the die attach film 3, detachability of the die attach film 3 can be enhanced. Furthermore, for example, an olefin-based backing material with a small surface tension, such as polypropylene and polyethylene, may also be used as the rigid backing layer 23. In this case, the rigid backing layer 23 on the elastic layer 22 side is preferably subjected to a corona treatment, a primer treatment or the like so as to enhance the adherence to the elastic layer 22.

Examples of the rigid backing layer 23 that can be used include commercial products available under the trade name of “TORAYFAN” (produced by Toray Industries, Inc.), the trade name of “Lumirror” (produced by Toray Industries, Inc.), the trade name of “ARTON” (produced by JSR Corp.), the trade name of “ZEONOR” (produced by ZEON Corp.), and the trade name of “Melinex” (produced by Teijin DuPont Films Japan Limited). Among these, commercial products available under the trade name of “Lumirror” (produced by Toray Industries, Inc.) and the trade name of “Melinex” (produced by Teijin DuPont Films Japan Limited) can be suitably used. The commercial product above may be appropriately subjected to a stretching treatment or a crosslinking treatment, if desired, and the surface thereof may be subjected to a corona treatment or a print processing treatment.

### (Pressure-Sensitive Adhesive Layer (A))

The pressure-sensitive adhesive layer (A) 24 may be a pressure-sensitive adhesive layer originally having small adhesive strength but is preferably a removable pressure-sensitive adhesive layer having a pressure-sensitive adhesiveness high enough to enable sticking to an adherend and, after the completion of predetermined role, allowing the pressure-sensitive adhesiveness to be decreased or lost by a certain method (an adhesion reducing treatment). Such a removable pressure-sensitive adhesive layer can have the same construction as that of the pressure-sensitive adhesive layer of a known removable pressure-sensitive adhesive sheet. In view of self-rolling property, the adhesive strength (180° peeling, vs. silicon mirror wafer, tensile rate: 300 mm/min) of the pressure-sensitive adhesive layer or the pressure-sensitive adhesive layer after an adhesion reducing treatment is, for example, at ordinary temperature (25° C.), preferably 6.5 N/10 mm or less (more preferably 6.0 N/10 mm or less).

Incidentally, in order to smoothly collect a chip possessing a supporting tape and a die attach film at the picking after the dicing of an adherend such as wafer, the adhesive strength of the pressure-sensitive adhesive layer (A) 24 in the supporting tape 2 with respect to the die attach film 3 must be set to become larger than the adhesive strength of the pressure-sensitive adhesive layer (B) 12 in the dicing tape 1 with respect to the heat contractible backing layer 21 in the supporting tape 2. However, in the case where the die attach film 3 itself has self-adhesiveness and the pressure-sensitive adhesive layer (A) 24 is not provided, the adhesive strength of the die attach film 3 with respect to the rigid backing layer 23 in the supporting tape 2 at the picking after dicing must be set to become larger than the adhesive strength of the pressure-sensitive adhesive layer (B) 12 in the dicing tape 1 with respect to the heat contractible backing layer 21 in the supporting tape 2.

The pressure-sensitive adhesive layer (A) 24 may be constituted of a pressure-sensitive adhesive (non-active energy ray-curable pressure-sensitive adhesive) or an active energy ray-curable pressure-sensitive adhesive. The pressure-sensitive adhesive layer (A) 24 is preferably an energy ray-curable pressure-sensitive adhesive layer (more preferably an active energy ray-curable pressure-sensitive adhesive layer). The energy ray-curable pressure-sensitive adhesive layer may be composed of a material that has adhesiveness/pressure-sensitive adhesiveness in the early stage but forms a three-dimensional network structure upon irradiation of an energy ray such as infrared ray, visible ray, ultraviolet ray, X-ray and electron beam to exhibit high elasticity, and an energy ray-curable pressure-sensitive adhesive or the like may be used as such a material. The energy ray-curable pressure-sensitive adhesive contains a compound chemically modified with an energy ray reactive functional group for imparting energy ray curability, or an energy ray-curing compound (or an energy ray-curing resin). Accordingly, the energy ray-curable pressure-sensitive adhesive that is preferably used is composed of a base material chemically modified with an energy ray reactive functional group or a composition in which an energy ray-curing compound (or an energy ray-curing resin) is blended in the base material.

The base material that can be used is, for example, a conventionally known adhesive material such as pressure-sensitive adhesive (adhesive). Examples of the pressure-sensitive adhesive include a rubber-based pressure-sensitive adhesive using, as the base polymer, natural rubber or a rubber-based polymer such as polyisobutylene rubber, styrene-butadiene rubber, styrene-isoprene-styrene block copolymer rubber, regenerated rubber, butyl rubber, polyisobutylene rubber and NBR; a silicone-based pressure-sensitive adhesive; and an acrylic pressure-sensitive adhesive. Among these, an acrylic pressure-sensitive adhesive is preferred. The base material may be composed of one kind or two or more kinds of components.

Examples of the acrylic pressure-sensitive adhesive include an acrylic pressure-sensitive adhesive using, as the base polymer, an acrylic polymer, for example, a homo- or co-polymer of an alkyl (meth)acrylate, such as C₁-C₂₀ alkyl (meth)acrylate, e.g., methyl (meth)acrylate, ethyl (meth)acrylate, butyl (meth)acrylate, 2-ethylhexyl (meth)acrylate, octyl (meth)acrylate; or a copolymer of an alkyl (meth)acrylate described above and other copolymerizable monomers [for example, a carboxyl group- or acid anhydride group-containing monomer such as acrylic acid, methacrylic acid, itaconic acid, fumaric acid and maleic anhydride; a hydroxyl group-containing monomer such as 2-hydroxyethyl (meth)acrylate; an amino group-containing monomer such as morpholyl (meth)acrylate; and an amide group-containing monomer such as (meth)acrylamide]. One of these may be used alone, or two or more thereof may be used in combination.

The energy ray reactive functional group used for chemical modification to ensure energy ray curing of an energy ray-curable adhesive and the energy ray-curing compound are not particularly limited as long as they are curable with an energy ray such as infrared ray, visible ray, ultraviolet ray, X-ray and electron beam, but those capable of efficiently causing three-dimensional network formation (networking) of the energy ray-curable pressure-sensitive adhesive after irradiation of an energy ray are preferred. One of these may be used alone, or two or more thereof may be used in combination. Examples of the energy ray reactive functional group for use in the chemical modification include a carbon-carbon multiple bond-containing functional group such as acryloyl group, methacryloyl group, vinyl group, allyl group and acetylene group. Such a functional group can produce a radical resulting from cleavage of the carbon-carbon multiple bond upon irradiation with an energy ray and form a three-dimensional network structure by letting the produce radical work out to a crosslinking point. Above all, a (meth)acryloyl group can exhibit relatively high reactivity for an energy ray and is preferred in view of reactivity and workability, for example, in that selection from an abundant variety of acrylic pressure-sensitive adhesives as well as their use in combination are allowed.

Typical examples of the base material chemically modified with an energy ray reactive functional group include a polymer obtained by reacting a reactive functional group-containing acrylic polymer resulting from copolymerization between a monomer containing a reactive functional group (e.g., hydroxyl, carboxyl) [a monomer such as 2-hydroxyethyl (meth)acrylate or (meth)acrylic acid] and an alkyl (meth)acrylate, with a compound having in its molecule a group capable of reacting with the reactive functional group, such as isocyanate group and epoxy group, and an energy ray reactive functional group (e.g., acryloyl, methacryloyl) [a compound such as (meth)acryloyloxyethylene isocyanate].

The ratio of the reactive functional group-containing monomer in the reactive functional group-containing acrylic polymer is, for example, from 5 to 40 wt %, preferably from 10 to 30 wt %, based on all monomers. At the reaction with the reactive functional group-containing acrylic polymer, the use amount of the compound having in its molecule a group capable of reacting with the reactive functional group and an energy ray reactive functional group is, for example, from 50 to 100 mol %, preferably from 60 to 95 mol %, based on the reactive functional group (e.g., hydroxyl, carboxyl) in the reactive functional group-containing acrylic polymer.

Examples of the energy ray-curing compound include a compound having two or more carbon-carbon double bonds, such as poly(meth)acryloyl group-containing compound, e.g., trimethylolpropane triacrylate, tetramethylolmethane tetraacrylate, pentaerythritol triacrylate, pentaerythritol tetraacrylate, dipentaerythritol monohydroxy pentaacrylate, dipentaerythritol hexaacrylate, 1,4-butanediol diacrylate, 1,6-hexanediol diacrylate, polyethylene glycol diacrylate. One of these compounds may be used alone, or two or more thereof may be used in combination. Above all, a poly(meth)acryloyl group-containing compound is preferred, and examples thereof are described, for example, in JP-A-2003-292916, herein incorporated by reference. The poly(meth)acryloyl group-containing compound is hereinafter sometimes referred to as an “acrylate-based crosslinking agent”.

As regards the energy ray-curing compound, for example, a mixture of organic salts such as onium salt and a compound having a plurality of heterocycles in its molecule may also be used. This mixture produces an ion resulting from cleavage of an organic salt upon irradiation with an energy ray and causes a ring-opening reaction of heterocycles by letting the produced ion work as an initiation species, whereby a three-dimensional network structure can be formed. Examples of the organic salts include an iodonium salt, a phosphonium salt, an antimonium salt, a sulfonium salt and a borate salt, and examples of the heterocycle in the compound having a plurality of heterocycles in its molecule include oxirane, oxetane, oxolane, thiirane and aziridine. Specific examples of the compound which can be used include compounds described in Hikari Koka Gijutsu (Photocuring Technology), edited by Gijutsu Joho Kyokai (Technical Information Association), (2000), herein incorporated by reference.

Examples of the energy ray curing resin include a photosensitive reaction group-containing polymer or oligomer such as ester (meth)acrylate having a (meth)acryloyl group at its molecular end, urethane (meth)acrylate, epoxy (meth)acrylate, melamine (meth)acrylate, acrylic resin (meth)acrylate, thiol-ene addition-type or cationic photopolymerization-type resin having an allyl group at its molecular end, cinnamoyl group-containing polymer (e.g., polyvinyl cinnamate), diazotated amino-novolak resin, and acrylamide-type polymer. Examples of the polymer capable of reacting with a higher energy ray include epoxidized polybutadiene, unsaturated polyester, polyglycidyl methacrylate, polyacrylamide and polyvinylsiloxane. Incidentally, in the case of using an energy ray-curing resin, the base material described above is not necessarily required.

In particular, the energy ray-curable pressure-sensitive adhesive is preferably a pressure-sensitive adhesive composed of a combination of the above-described acrylic polymer or acrylic polymer chemically modified with an energy ray reactive functional group (an acrylic polymer where an energy ray reactive functional group is introduced into the side chain) and the above-described energy ray-curing compound (for example, a compound having two or more carbon-carbon double bonds). The combination above is preferred in view of reactivity and workability, because an acrylate group exhibiting relatively high reactivity for an energy ray is contained and selection from a variety of acrylic pressure-sensitive adhesives is allowed. Specific examples of this combination include a combination of an acrylic polymer having introduced into the side chain an acrylate group and a compound having two or more carbon-carbon double bond-containing functional groups (particularly acrylate group). As for such a combination, those disclosed, for example, in JP-A-2003-292916, herein incorporated by reference, can be used.

Examples of the preparation method of the acrylic polymer having introduced into the side chain thereof an acrylate group include a method of bonding an isocyanate compound such as acryloyloxyethyl isocyanate and methacryloyloxyethyl isocyanate to an acrylic polymer containing a hydroxyl group in its side chain, through a urethane bond.

The amount of the energy ray-curing compound blended is, for example, approximately from 0.5 to 200 parts by weight, preferably from 5 to 180 parts by weight, more preferably on the order of 20 to 130 parts by weight, per 100 parts by weight of the base material (for example, the above-described acrylic polymer or acrylic polymer chemically modified with an energy ray reactive functional group).

In the energy ray-curable pressure-sensitive adhesive, for the purpose of increasing the speed of reaction to form a three-dimensional network structure, an energy ray polymerization initiator for curing the compound that imparts energy ray curability may be blended.

The energy ray polymerization initiator can be appropriately selected from conventionally known or employed polymerization initiators according to the kind of the energy ray used (for example, infrared ray, visible ray, ultraviolet ray, X-ray or electron beam). In view of working efficiency, a compound capable of initiating photopolymerization with ultraviolet ray is preferred. Typical examples of the energy ray polymerization initiator include, but are not limited to, a ketone-based initiator such as benzophenone, acetophenone, quinone, naphthoquinone, anthraquinone and fluorenone; an azo-based initiator such as azobisisobutyronitrile; and a peroxide-based initiator such as benzoyl peroxide and perbenzoic acid. Examples of the commercial product include those available under the trade names of “IRGACURE 184” and “IRGACURE 651”, produced by Ciba-Geigy Corp.

One of these energy ray polymerization initiators may be used alone, or two or more thereof may be mixed and used. The amount of the energy ray polymerization initiator blended is usually on the order of 0.01 to 10 parts by weight, preferably on the order of 1 to 8 parts by weight, per 100 parts by weight of the above-described base material. Incidentally, together with the energy ray polymerization initiator, an energy ray polymerization accelerator may be used in combination, if desired.

In the energy ray-curable pressure-sensitive adhesive, other than the components described above, an additive for obtaining an appropriate pressure-sensitive adhesiveness before and after the energy ray curing, such as crosslinking agent, curing (crosslinking) accelerator, tackifier, vulcanizing agent and thickener, and an additive for enhancing the durability, such as age resistor and antioxidant, are blended, if desired.

The energy ray-curable pressure-sensitive adhesive used is preferably, for example, a composition in which an energy ray-curing compound is blended in a base material (pressure-sensitive adhesive), more preferably a UV-curable pressure-sensitive adhesive in which a UV-curing compound is blended in an acrylic pressure-sensitive adhesive. In particular, the preferred embodiment of the energy ray-curable pressure-sensitive adhesive is an UV-curable pressure-sensitive adhesive containing a side chain acrylate-containing acrylic pressure-sensitive adhesive, an acrylate-based crosslinking agent (a poly(meth)acryloyl group-containing compound; a polyfunctional acrylate) and an ultraviolet photo-initiator. The side chain acrylate-containing acrylic pressure-sensitive adhesive means an acrylic polymer in which an acrylate group is introduced into the side chain, and the same as those described above can be prepared by the same method. The acrylate-based crosslinking agent is a low molecular compound exemplified above as the poly(meth)acryloyl group-containing compound. As for the ultraviolet photo-initiator, those exemplified above as typical energy ray polymerization initiators can be used.

Incidentally, in the case where the pressure-sensitive adhesive layer (A) 24 is constituted of an energy ray-curable pressure-sensitive adhesive, the adhesive strength (180° peeling, vs. silicon mirror wafer, tensile rate: 300 mm/min) after energy ray irradiation is generally 0.5 N/10 mm or less at ordinary temperature (25° C.).

In addition, a non-energy ray-curable pressure-sensitive adhesive using the above-described acrylic pressure-sensitive adhesive as the base material may also be used as the pressure-sensitive adhesive constituting the pressure-sensitive adhesive layer (A) 24. In this case, those having an adhesive strength smaller than the peeling stress at the production of a cylindrical roll are applicable, and for example, a pressure-sensitive adhesive having an adhesive strength of 6.5 N/10 mm or less (for example, from 0.05 to 6.5 N/10 mm, preferably from 0.2 to 6.5 N/10 mm), particularly 6.0 N/10 mm or less (for example, from 0.05 to 6.0 N/10 mm, preferably from 0.2 to 6.0 N/10 mm), in a 180° peeling test (room temperature (25° C.)) using a silicon mirror wafer as the adherend, can be used. However, as described above, at the picking after wafer dicing, the adhesive strength of the pressure-sensitive adhesive layer (A) 24 with respect to the die attach film 3 must be larger than the adhesive strength of the pressure-sensitive adhesive layer (B) 12 in the dicing tape 1 with respect to the heat contractible backing layer 21 in the supporting tape 2.

Preferred examples of the non-energy ray-curable pressure-sensitive adhesive using an acrylic pressure-sensitive adhesive having small adhesive strength as the base material include an acrylic pressure-sensitive adhesive obtained by preparing a copolymer of an alkyl (meth)acrylate [for example, a C₁-C₂₀ alkyl (meth)acrylate such as methyl (meth)acrylate, ethyl (meth)acrylate, butyl (meth)acrylate, 2-ethylhexyl (meth)acrylate and octyl (meth)acrylate], a reactive functional group-containing monomer [for example, a carboxyl group- or acid anhydride group-containing monomer such as acrylic acid, methacrylic acid, itaconic acid, fumaric acid and maleic anhydride; a hydroxyl group-containing monomer such as 2-hydroxyethyl (meth)acrylate; an amino group-containing monomer such as morpholinyl (meth)acrylate; or an amide group-containing monomer such as (meth)acrylamide] and, if desired, other copolymerizable monomers [for example, an alicylcic hydrocarbon group-containing (meth)acrylic acid ester such as isobornyl (meth)acrylate, and acrylonitrile], adding a crosslinking agent capable of reacting with the reactive functional group [for example, an isocyanate-based crosslinking agent, a melamine-based crosslinking agent or an epoxy-based crosslinking agent] to the copolymer, and performing crosslinking.

The pressure-sensitive adhesive layer (A) 24 can be formed using a conventional method, for example, by a method of coating a surface of the rigid backing layer 23 with a coating solution prepared by adding a pressure-sensitive adhesive, an energy ray-curable compound and, if desired, a solvent; or a method of coating the above-described coating solution on an appropriate release liner (separator) to form a pressure-sensitive adhesive layer, and transferring (transfer-fixing) this layer onto the rigid backing layer 23. In the case of formation by transfer, a void (air gap) sometimes remains at the interface with the rigid backing layer 23. In this case, the void can be caused to diffuse and disappear by applying a warming/pressurization treatment such as an autoclave treatment. The pressure-sensitive adhesive layer (A) 24 may be either a single layer or a multlayer.

To the constituent components of the pressure-sensitive adhesive layer (A) 24 for use in the present invention, beads such as glass bead and resin bead may be further added. When grass or resin beads are added to the pressure-sensitive adhesive layer (A) 24, the shear modulus is readily increased to lower the adhesive strength. The average particle diameter of the beads is, for example, from 1 to 100 μm, preferably on the order of 1 to 20 μm. The addition amount of the beads is, for example, from 25 to 200 parts by weight, preferably from 50 to 100 parts by weight, per 100 parts by weight of the entire pressure-sensitive adhesive layer (A) 24. If the addition amount is excessively large, poor dispersion sometimes occurs, making it difficult to coat the pressure-sensitive adhesive, whereas if it is too small, the above-described effect tends to be insufficient.

The thickness of the pressure-sensitive adhesive layer (A) 24 can be appropriately selected by taking into consideration the cuttability and the like but is generally from 1 to 50 μm, preferably from 3 to 30 μm, more preferably from 5 to 15 μm. If the thickness is too small, the adhesive strength is insufficient and therefore, it becomes difficult to hold and temporarily fix an adherend, whereas if the thickness is excessively large, this is unprofitable and also, the cuttability and handleability are disadvantageously poor.

The pressure-sensitive adhesive layer (A) has a function of holding a die attach film 3 when separating the supporting tape 2 together with the chip and the die attach film from the dicing tape 1 surface in the picking step. After the completion of the picking step, owing to the low pressure-sensitive adhesiveness or application of an adhesion reducing treatment, self-rolling separation of the supporting tape 2 is not inhibited. Accordingly, the supporting tape 2 can be smoothly removed from the die attach film 3.

The supporting tape 2 can be produced as follows. The heat contractible backing layer 21, the elastic layer 22 and the rigid backing layer 23 are superposed and laminated by appropriately and selectively using a lamination device such as hand roller and laminator or an atmospheric pressure compressing device such as autoclave, according to the purpose, and the pressure-sensitive adhesive layer (A) 24 is provided on the surface of the rigid backing layer 23 of the obtained laminate sheet; or the rigid backing layer 23 having previously provided on one surface thereof the pressure-sensitive adhesive layer (A) 24 is superposed on the heat contractible backing layer 21 and the elastic layer 22, and these layers are laminated together.

In the supporting tape 2, from the standpoint of protection, blocking prevention and the like of the pressure-sensitive adhesive layer (A) 24 surface, a separator (release liner) may be provided on the pressure-sensitive adhesive layer (A) 24 surface. The separator is peeled off when sticking the supporting tape 2 to the die attach film 3. The separator used is not particularly limited and, for example, a conventionally known or employed release paper can be used. Examples of the separator which can be used include a backing material having a release layer (e.g., plastic film, paper) surface-treated with a release agent such as silicone type, long-chain alkyl type, fluorine type and molybdenum sulfide type; a low adhesive backing material composed of a fluorine-based polymer such as polytetrafluoroethylene, polychlorotrifluoroethylene, polyvinyl fluoride, polyvinylidene fluoride, tetrafluoroethylene-hexafluoropropylene copolymer and chlorofluoroethylene-vinylidene fluoride copolymer; and a low adhesive backing material composed of a non-polar polymer such as olefin-based resin (e.g., polyethylene, polypropylene). Also, in the supporting tape 2, an undercoat layer or an intermediate layer may be provided between respective layers, if desired.

The supporting tape 2 imparts rigidity to an adherend such as wafer by attaching to the adherend such as wafer, so that, for example, even at the picking of an ultrathin adherend, occurrence of pickup failure due to deflection of the adherend can be prevented. After the completion of picking, a stimulus such as heat that causes contraction is applied [in the case of using an active energy ray-curable pressure-sensitive adhesive layer for the pressure-sensitive adhesive layer (A) 24, after the irradiation of an active energy ray, a stimulus such as heat is applied] before the die bonding step, whereby the heat contractible backing layer 21 is contracted and the supporting tape 2 is separated while self-rolling to form a roll. Therefore, the supporting tape can be very easily removed without damaging an ultrathin wafer or contaminating the ultrathin wafer due to incomplete separation.

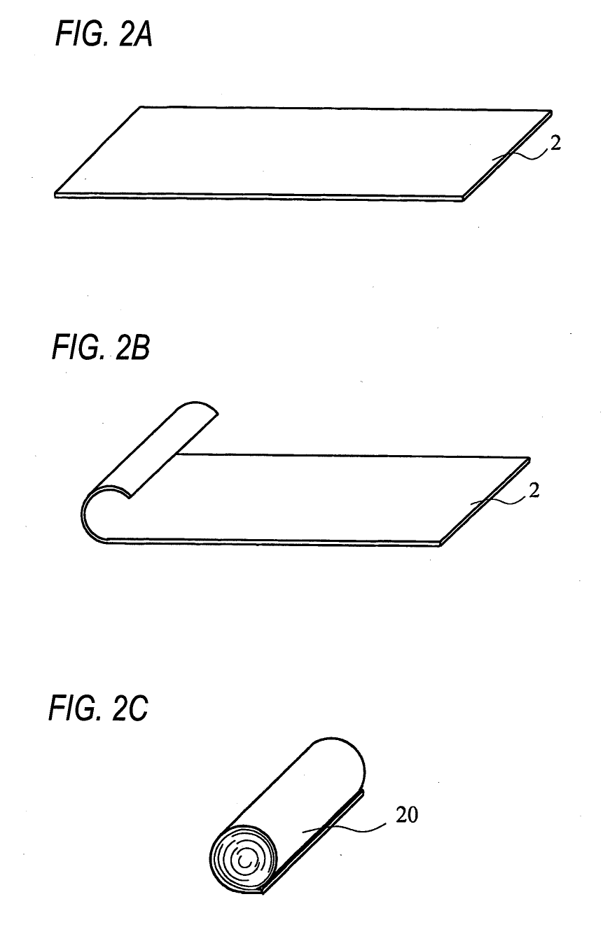

FIGS. 2A to 2C are views (perspective views) showing, as one example, how the supporting tape 2 for use in the present invention undergoes self-rolling separation. FIG. 2A is a view showing the supporting tape 2 before applying a thermal stimulus that causes contraction of the heat contractible film layer; FIG. 2B is a view showing a state where the supporting tape 2 after applying a contraction-causing thermal stimulus to the heat contractible backing layer starts rolling from the outer edge of sheet (one end part) in one direction (usually, in the main contraction axis direction of the heat contractible backing layer); and FIG. 2C is a view showing a state where rolling of the sheet is completed and one cylindrical roll is formed (one-direction rolling). Incidentally, there is also a case where the sheet undergoes self-rolling from two opposing end parts (usually, in the main contraction axis direction of the heat contractible backing layer) to form two cylindrical rolls (two-direction rolling). Whether the supporting tape 2 causes one-direction rolling or two-direction rolling varies depending on, for example, the adhesive strength of the restriction layer (elastic layer 22+rigid backing layer 23) with respect to the heat contractible backing layer 21 or the shear modulus of the restriction layer (particularly elastic layer 22).

### Die Attach Film

The die attach film 3 is a film-shaped adhesive used when adhering a semiconductor chip or the like to a die pad part, and a known die attach film can be used. The die attach film 3 is preferably composed of a resin composition containing an epoxy resin, because, for example, ionic impurities corroding the semiconductor chip are little contained.

The blending ratio of the epoxy resin in the resin composition can be appropriately selected from the range of 5 wt % or more (preferably 7 wt % or more, more preferably 9 wt % or more) based on the total amount of polymer components. Incidentally, the upper limit of the blending ratio of the epoxy resin is not particularly limited and is 100 wt % or less, preferably 50 wt % or less (more preferably 40 wt % or less), based on the total amount of polymer components.

The epoxy resin is not particularly limited as long as it is an epoxy resin generally used as an adhesive composition, and examples of the epoxy resin which can be used include a bifunctional epoxy resin and a polyfunctional epoxy resin, such as bisphenol A-type epoxy resin, bisphenol F-type epoxy resin, bisphenol S-type epoxy resin, brominated bisphenol A-type epoxy resin, hydrogenated bisphenol A-type epoxy resin, bisphenol AF-type epoxy resin, biphenyl-type epoxy resin, naphthalene-type epoxy resin, fluorene-type epoxy resin, phenol novolak-type epoxy resin, orthocresol novolak-type epoxy resin, trishydroxyphenylmethane-type epoxy resin and tetraphenylolethane-type epoxy resin; a hydantoin-type epoxy resin; a trisgycidyl isocyanurate-type epoxy resin; and a glycidylamine-type epoxy resin. One epoxy resin may be used alone, or two or more epoxy resins may be used in combination.

Among the epoxy resins above, a novolak-type epoxy resin, a biphenyl-type epoxy resin, a trishydroxyphenylmethane-type epoxy resin and a tetraphenylolethane-type epoxy resin are preferred, because these epoxy resins are rich in reactivity with a phenol resin as a curing agent and excellent in heat resistance and the like.

In the resin composition constituting the die attach film 3, other thermosetting resins or thermoplastic resins can be blended, if desired. Example of the thermosetting resin include a phenol resin, an amino resin, an unsaturated polyester resin, a polyurethane resin, a silicone resin and a thermosetting polyimide resin. One of these thermosetting resins may be used alone, or two or more thereof may be mixed and used.

The phenol resin acts as a curing agent of the epoxy resin, and examples thereof include a novolak-type phenol resin such as phenol novolak resin, phenol aralkyl resin, cresol novolak resin, tert-butylphenol novolak resin and nonylphenol novolak resin; a resol-type phenol resin; and a polyoxystyrene such as polyparaoxystyrene. One of these may be used alone, or two or more thereof may be used in combination. Among these phenol resins, a phenol novolak resin and a phenol aralkyl resin are preferred in that the connection reliability of a semiconductor device can be enhanced.

As regards the blending ratio of the phenol resin, for example, the phenol resin is preferably blended such that the hydroxyl group in the phenol resin becomes 0.5 to 2.0 equivalents (preferably from 0.8 to 1.2 equivalent) per 1 equivalent of the epoxy group in the epoxy resin component. If the blending ratio of the phenol resin is outside the range above, the curing reaction does not proceed sufficiently, and the epoxy resin cured product is liable to deteriorate in its properties.

Examples of the thermoplastic resin include natural rubber, butyl rubber, isoprene rubber, chloroprene rubber, an ethylene-vinyl acetate copolymer, an ethylene-acrylic acid copolymer, an ethylene-acrylic acid ester copolymer, a polybutadiene resin, a polycarbonate resin, a thermoplastic polyimide resin, a polyamide resin such as 6-nylon and 6,6-nylon, a phenoxy resin, an acrylic resin, a saturated polyester resin such as PET and PBT, a polyamideimide resin and a fluororesin. One of these thermoplastic resins may be used alone, or two or more thereof may be used in combination. Among these thermoplastic resins, an acrylic resin having little ionic impurities and high heat resistance and ensuring reliability of a semiconductor element is preferred.

The acrylic resin is not particularly limited, and examples thereof include a polymer composed of one ester or two or more esters of an acrylic or methacrylic acid containing a linear or branched alkyl group having a carbon number of 30 or less, particularly a carbon number of 4 to 18. Examples of the alkyl group include a methyl group, an ethyl group, a propyl group, an isopropyl group, an n-butyl group, a tert-butyl group, an isobutyl group, a pentyl group, an isopentyl group, a hexyl group, a heptyl group, a 2-ethylhexyl group, an octyl group, an isooctyl group, a nonyl group, an isononyl group, a decyl group, an isodecyl group, an undecyl group, a dodecyl group (lauryl group), a tridecyl group, a tetradecyl group, a stearyl group and an octadecyl group.

The other monomer component (a monomer except for an ester of an acrylic or methacrylic acid having a carbon number of 30 to less) is not particularly limited, and examples thereof include a carboxyl group-containing monomer such as (meth)acrylic acid, carboxyethyl acrylate, carboxypentyl acrylate, itaconic acid, maleic acid, fumaric acid and crotonic acid, an acid anhydride monomer such as maleic anhydride and itaconic anhydride, a hydroxyl group-containing monomer such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate, a sulfonic acid group-containing monomer such as styrenesulfonic acid, allylsulfonic acid, 2-(meth)acrylamido-2-methylpropanesulfonic acid, (meth)acrylamidopropanesulfonic acid, sulfopropyl (meth)acrylate and (meth)acryloyloxynaphthalenesulfonic acid, and a phosphoric acid group-containing monomer such as 2-hydroxyethylacryloyl phosphate.

In the present invention, the thermoplastic resin (particularly acrylic resin) can be used in a ratio of less than 90 wt % (for example, from 1 to 90 wt %) based on the total amount of polymer components containing an epoxy resin. The ratio of the thermoplastic resin such as acrylic resin is preferably from 20 to 85 wt %, more preferably from 40 to 80 wt %, based on the total amount of polymer components.

The epoxy resin-containing resin composition is preferably crosslinked to a certain extent in advance, and a polyfunctional compound capable of reacting with a functional group or the like at the molecular chain terminal of the resin composition is preferably added as the crosslinking agent. Thanks to this addition, the adhesive properties at a high temperature can be enhanced to improve heat resistance.

Furthermore, in the epoxy resin-containing resin composition, other additives may be appropriately blended, if desired. Examples of other additives include a flame retardant, a silane coupling agent, an ion trapping agent, a coloring agent, an extender, a filler, an age resistor, an antioxidant and a surfactant. Examples of the flame retardant include antimony trioxide, antimony pentoxide and brominated epoxy resin. Examples of the silane coupling agent include β-(3,4-epoxycyclohexyl)ethyltrimethoxysilane, γ-glycidoxypropyltrimethoxysilane and γ-glycidoxypropylmethyldiethoxysilane. Examples of the ion trapping agent include hydrotalcites and bismuth hydroxide. One of these may be used alone, or two or more thereof may be used in combination.

The die attach film 3 may have, for example, a single-layer structure of an adhesive layer (die adhesive layer) formed of the epoxy resin-containing resin composition, or may have a multilayer structure of two or more layers by appropriately combining, in addition to the epoxy resin, thermosetting resins differing in the glass transition temperature or thermosetting resins differing in the thermosetting temperature.

In the dicing step of a semiconductor wafer, water for cutting is used and therefore, the die attach film sometimes absorbs moisture to have a water content higher than in an ordinary state. If the die attach film having such a high water content is adhered as it is to a die pad part, water vapor may accumulate in the adhesion interface at an after-cure stage to cause lifting. To avoid this, the die attach film may be constructed to have a multilayer structure where a highly hygroscopic core material is sandwiched between adhesive layers (die adhesive layers) each formed of the epoxy resin-containing resin composition. Owing to such a construction, water vapor diffuses through the core material at the after-cure stage and the above-described problem can be avoided.

Examples of the core material include a film (e.g., polyimide film polyester film, polyethylene terephthalate film, polyethylene naphthalate film, polycarbonate film), a resin substrate reinforced with glass fiber or plastic-made nonwoven fiber, a silicon substrate, and a glass substrate.

The thickness of the die attach film 3 is not particularly limited but is, for example, approximately from 5 to 100 μm, preferably on the order of 5 to 50 μm.

Die Attach Film-Provided Dicing tape

The die attach film-provided dicing tape 4 of the present invention, where the above-described dicing tape 1, supporting tape 2 and die attach film 3 are laminated in this order, is not particularly limited in its production method and, for example, can be produced by a conventional method used for the production of a laminate, such as coating and lamination. In the present invention, a method of separately producing the dicing tape, the supporting tape and the die attach film, and then performing lamination is preferred, because various laminates according to the purpose can be easily produced. The die attach film-provided dicing tape of the present invention may have an arbitrary shape such as sheet and tape.

In the die attach film-provided dicing tape 4 of the present invention, the surface on the die attach film 3 side is preferably protected by a separator (release liner) (not shown). The separator has a function as a protective material that protects the die attach film 3 until it is used in practice. The separator can also be used as a support backing material when transferring the die attach film 3 to the pressure-sensitive adhesive layer (A) 24 of the supporting tape 2. The separator is peeled off when a semiconductor wafer or the like is stuck on the die attach film 3 of the die attach film-provided dicing tape 4.

The separator is not particularly limited, and a conventionally known or employed release paper and the like can be used. Examples of the separator which can be used include a backing material having a release layer such as plastic film ((e.g., polyethylene terephthalate film) or paper, which is surface-treated with a release agent such as silicone type, long-chain alkyl type, fluorine type and molybdenum sulfide type; a low adhesive backing material composed of a fluorine-based polymer such as polytetrafluoroethylene, polychlorotrifluoroethylene, polyvinyl fluoride, polyvinylidene fluoride, tetrafluoroethylene-hexafluoropropylene copolymer and chlorofluoroethylene-vinylidene fluoride copolymer; and a low adhesive backing material composed of a non-polar polymer such as olefin-based resin (e.g., polyethylene, polypropylene). Incidentally, the separator can be formed by a conventionally known method. Also, the separator is not particularly limited in its thickness and the like.

According to the die attach film-provided dicing tape of the present invention, a supporting tape having specific properties intervenes between the dicing tape and the die attach film, so that even a fragile adherend can be imparted with appropriate rigidity and its processing or picking can be smoothly performed. In turn, high yield can be achieved, for example, in the individualization and collection of a silicon wafer, a compound semiconductor (e.g., gallium-arsenic), sapphire or MEMS (micro-electromechanical systems).

### Production Process of Semiconductor Device

The production process of a semiconductor device of the present invention includes steps of laminating a semiconductor wafer to a die attach film surface of the above-described die attach film-provided dicing tape of the present invention to form a laminate structure of dicing tape/supporting tape/die attach film/wafer; and dicing the resulting laminate structure from the wafer side, followed by pushing it up from the dicing tape side, thereby collecting a semiconductor chip possessing the supporting tape and the die attach film.

The production process of a semiconductor device of the present invention may further include a step of allowing the supporting tape to undergo self-rolling separation from the collected semiconductor chip possessing the supporting tape and the die attach film to obtain a semiconductor chip possessing the die attach film, and may further include a step of bonding the obtained semiconductor chip possessing the die attach film to a die pad part.

In this production process, a semiconductor chip possessing a die attach film may be obtained by collecting a semiconductor chip possessing the supporting tape and the die attach film by means of a pickup adsorption collet equipped with a heating mechanism, and heating the supporting tape to undergo self-rolling separation from the collected semiconductor chip possessing the supporting tape and the die attach film.

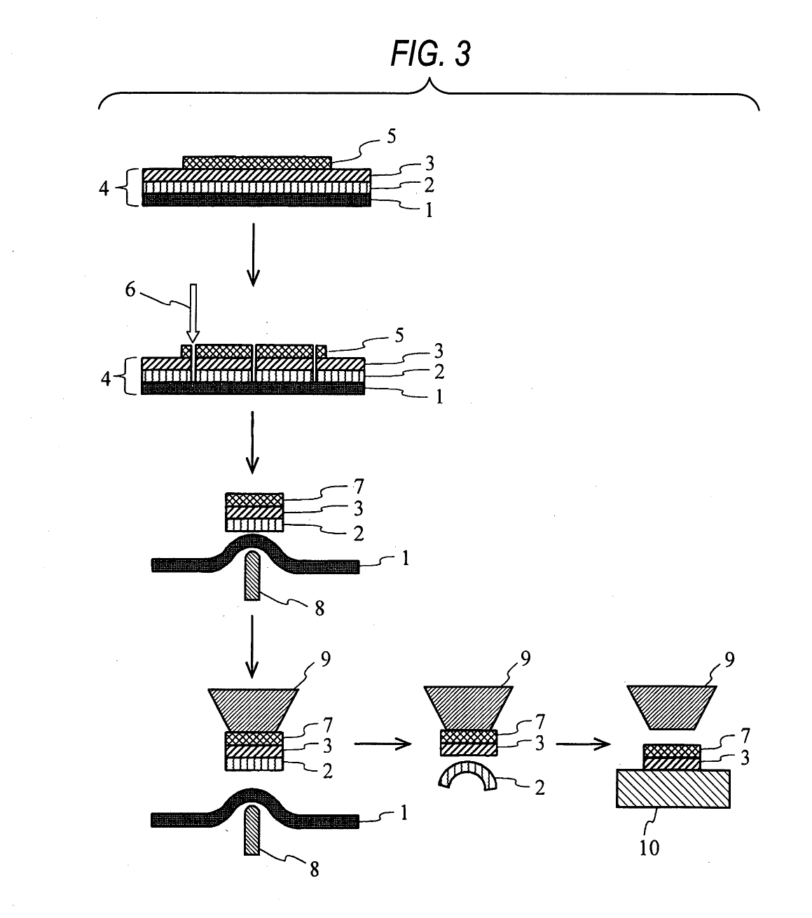

FIG. 3 is a schematic view (cross-sectional view) showing one example of the production process of a semiconductor device of the present invention, including the following steps, that is,

(1) laminating a semiconductor wafer 5 to the die attach film surface of a die attach film-provided dicing tape 4, which is composed of dicing tape 1/supporting tape 2/die attach film 3 (wafer mounting),

(2) cutting the laminate structure of dicing tape 1/supporting tape 2/die attach film 3/wafer 5 from the wafer 5 side by using a dicer 6 to a depth deep enough to completely cut the supporting tape 2 (dicing),

(3) pushing up the laminate structure from the dicing tape 1 side by using a pickup needle 8 (picking),

(4) collecting a chip 7 with the supporting tape 2 and the die attach film 3 by using a heater collet 9 (picking),

(5) allowing the supporting tape 2 to undergo self-rolling separation due to heat of the heater collet 9, and

(6) fixing the chip 7 with the die attach film 3 on a die pad part 10 (die bonding).

A series of steps for producing a semiconductor device usually include a mounting step, a dicing step, a picking step, a die bonding step and the like. The mounting step is a step of laminating a semiconductor wafer 5 and a die attach film-provided dicing tape 4, which has a laminate structure of dicing tape 1/supporting tape 2/die attach film 3, to form a laminate structure of dicing tape 1/supporting tape 2/die attach film 3/wafer 5. The method for lamination includes, for example, a method of superposing a semiconductor wafer 5 and a die attach film-provided dicing tape 4 by arranging the die attach film 3 side to become the lamination surface, and pressing them by a pressing device such as pressure roller. Also, lamination can be performed by superposing a semiconductor wafer 5 and a die attach film-provided dicing tape 4 as above in a pressurizable container (for example, autoclave) and pressurizing the inside of the container. At this time, the semiconductor wafer and the dicing tape may be laminated while pressing them by an appropriate pressing device. Furthermore, the wafer and the dicing tape may be laminated together in the same manner as above in a vacuum chamber. The temperature when laminating these together is not particularly limited but is preferably from 20 to 80° C.

The dicing step is a step of individualizing the semiconductor wafer to produce a semiconductor chip(s). In the present invention, dicing is performed from the wafer 5 side of the laminate structure of dicing tape 1/supporting tape 2/die attach film 3/wafer 5 obtained in the mounting step. The cutting depth is sufficient if it is deep enough to enable separation of the chip possessing the supporting tape and the die attach film from the surface of the dicing tape 1 (that is, a state where the members from the wafer 5 to the supporting tape 2 are completely cut). The dicing tape may be partially cut. The dicing apparatus is not particularly limited, and a known dicing apparatus can be used.

In the case of using an active energy ray-curable pressure-sensitive adhesive layer as the pressure-sensitive adhesive layer (A) 24 and/or the pressure-sensitive adhesive layer (B) 12, the pressure-sensitive adhesive layer is preferably cured by irradiating an active energy ray after the dicing step but before the picking step. The adhesive strength is reduced resulting from curing of the pressure-sensitive adhesive layer, whereby the individualized laminate of supporting tape/die attach film/chip (a chip possessing the supporting tape and the die attach film) can be easily separated from the dicing tape 1 and picking can be smoothly performed. Also, thereafter, the supporting tape 2 is allowed to smoothly undergo self-rolling separation from the die attach film 3, and a chip possessing the die attach film can be obtained.

The device for active energy ray exposure may be sufficient if the active energy ray-curable pressure-sensitive adhesive can be cured, and for example, an ultraviolet ray exposure device using a light source capable of efficiently producing an ultraviolet ray, such as high-pressure mercury lamp, can be used. The irradiation conditions at the active energy ray irradiation, such as irradiation intensity and irradiation time, are not particularly limited and can be appropriately set as needed. For example, in the case of using an ultraviolet ray as the active energy ray, light at an integrated light quantity of approximately from 50 to 1,000 mJ/cm² is irradiated.

The chip picking step is a step of separating and collecting a chip possessing a supporting tape and a die attach film (individualized laminate of supporting tape/die attach film/wafer), which is fixed to a dicing tape 1 by adhesion, from the dicing tape 1. The method for picking is not particularly limited, and conventionally known various methods may be employed. Examples thereof include a method of pushing up individual chips from the dicing tape 1 side by a needle, and collecting the pushed-up chip by an adsorption collet. By virtue of using the die attach film-provided dicing tape of the present invention, even when the chip is very thinly polished (even an ultrathin chip), the supporting tape 2 can impart appropriate rigidity to the chip, so that occurrence of pickup failure due to deflection of the chip pushed up by a needle can be prevented. Also, a fragile ultrathin chip can be prevented from being damaged by the pushing up with a needle.

In the present invention, the supporting tape 2 of the chip possessing the supporting tape and the die attach film is heated after the picking step but before the die bonding step, whereby the supporting tape 2 is caused to undergo self-rolling separation. In particular, a method of collecting the chip possessing the supporting tape and the die attach film by using a pickup adsorption collet equipped with a heating mechanism (heating unit), heating the supporting tape 2 to undergo self-rolling separation, and bonding the chip possessing the die attach film to a die pad part 10 is preferred. Owing to the self-rolling separation of the supporting tape 2, the labor for peeling can be saved, the process can immediately proceed to the die bonding step, and high productivity can be realized. Furthermore, a fragile ultrathin chip can be prevented from being damaged by peeling.

The heating temperature and heating time for causing the supporting tape 2 to undergo self-rolling separation can be appropriately adjusted according to the heat capacity of chip and die attach film, the ambient temperature of apparatus, and the transport time from the picking site to the site where the supporting tape is separated and collected. The heating temperature is, for example, from 60 to 180° C., preferably from 70 to 140° C., and the heating time is, for example, approximately from 5 to 180 seconds.

The site where the supporting tape is separated and collected is preferably provided between the picking site and the die bonding site. As regards the method for separating and collecting the supporting tape formed into a cylindrical roll, an appropriate method, for example, a method of collection by blowing with an air gun or the like, a method of collection by adhesion with a collecting tape (pressure-sensitive adhesive tape), and a method of collection by a jig (scraper), can be employed.

The die bonding step is a step of adhering the chip possessing the die attach film to a die pad part 10 (die-attaching to the substrate or lower chip). After adhering to the die pad part 10, a treatment such as wire bonding and mold encapsulation is applied. In the present invention, since the die attach film 3 in a chip size is uniformly sticking to the back surface, a problem such as bleeding in the case of using a liquid adhesive or inclination of the chip due to non-uniform coating of an adhesive does not arise. Furthermore, the process is performed using one tape from the dicing step to the die bonding step and therefore, as compared with the case of using a dicing tape and a die attach film, the step of laminating together a die attach film and a chip can be omitted, so that the damage to a wafer due to heat treatment at the lamination can be eliminated and at the same time, simplification of the process can be realized.

### EXAMPLES

The present invention is described in greater detail below by referring to Examples, but the present invention is not limited to these Examples.

### Production Example 1

### Production of Die Attach Film

Based on 100 parts by weight of an acrylic acid ester-based polymer mainly composed of ethyl acrylate-methyl methacrylate (“PARACRON W-197CM”, trade name, produced by Negami Chemical Industrial Co., Ltd.), 59 parts by weight of an epoxy resin (“EPIKOTE 1004”, produced by JER), 53 parts by weight of an epoxy resin (“EPIKOTE 827”, trade name, produced by JER), 121 parts by weight of a phenolic resin (“MILEX XLC-4L”, trade name, produced by Mitsui Chemicals, Inc.) and 222 parts by weight of spherical silica (“SO-25R”, trade name, produced by Admatechs Co., Ltd.) were dissolved in methyl ethyl ketone to prepare an adhesive composition solution having a solid content concentration of 23.6 wt %. The obtained adhesive composition solution was coated on a PET film (thickness: 38 μm) release-treated with silicone as a release liner (separator), and then dried at 130° C. for 2 minutes to produce a 20 μm-thick die attach film.

### Production Example 2-1

### Production of Pressure-Sensitive Adhesive Layer

Based on 100 parts by weight of an acrylic copolymer (obtained by copolymerizing 2-ethylhexyl acrylate/morpholyl acrylate/acrylic acid/2-hydroxyethyl acrylate=75/25/3/0.1 (by weight)], 2 parts by weight of a crosslinking agent (“TETRAD-C”, trade name, produced by Mitsubishi Gas Chemical Industries Ltd.), 2 parts by weight of a crosslinking agent (“Coronate L”, trade name, produced by Nippon Polyurethane Industry Co., Ltd.) and 0.05 parts by weight of “EPAN 710” (trade name, produced by Daiichi Kogyo Seiyaku Co., Ltd.) were mixed to prepare a pressure-sensitive adhesive (non-active energy ray-curable pressure-sensitive adhesive).

The obtained pressure-sensitive adhesive was coated on a release sheet (“MRF38”, trade name, produced by Mitsubishi Polyester Film Corp.) by using an applicator, and volatiles such as solvent were dried to obtain a 30 μm-thick pressure-sensitive adhesive layer.

### Production Example 2-2

### Production of Active Energy Ray-Curable Pressure-Sensitive Adhesive Layer

An acrylic polymer having a methacrylate group in the side chain was produced by bonding 60% of 2-hydroxyethyl acrylate-derived hydroxyl group in an acrylic polymer [composition: obtained by copolymerizing 2-ethylhexyl acrylate/morpholyl acrylate/2-hydroxyethyl acrylate=70/30/20 (by weight)] to methacryloyloxyethyl isocyanate (2-isocyanatoethyl methacrylate). Based on 100 parts by weight of the acrylic polymer having a methacrylate group in the side chain, 50 parts by weight of a compound containing two or more functional groups having a carbon-carbon double bond (“SHIKO UV1700”, trade name, produced by The Nippon Synthetic Chemical Industry Co., Ltd.), 3 parts by weight of photoinitiator (“IRGACURE 184”, trade name, produced by Ciba Japan) and 3.5 parts by weight of crosslinking agent (“Coronate L”, trade name, produced by Nippon Polyurethane Industry Co., Ltd.) were mixed to prepare an energy ray-curable pressure-sensitive adhesive.

The obtained energy ray-curable pressure-sensitive adhesive was coated on a release sheet (“MRF38”, trade name, produced by Mitsubishi Polyester Film Corp.) by using an applicator, and volatiles such as solvent were dried to obtain a 30 μm-thick energy ray-curable pressure-sensitive adhesive layer.

### Production Example 3-1

### Production of Heat Contractible Backing Layer/Elastic Layer/Rigid Backing Layer

An ester-based polymer was obtained from 100 parts by weight of “PLACCEL CD220PL” (trade name, produced by Daicel Chemical Industries, Ltd.) and 10 parts by weight of sebacic acid. A solution prepared by mixing 4 parts by weight of crosslinking agent (“Coronate L”, trade name, produced by Nippon Polyurethane Industry Co., Ltd.) per 100 parts by weight of the ester-based polymer was coated on one surface of a polyethylene terephthalate film (“Lumirror S10”, trade name, produced by Toray Industries, Inc., thickness: 50 μm) as a rigid backing layer to have a dry thickness of 30 μm, a uniaxially stretched polyester film (“SPACECLEAN S5630”, trade name, produced by Toyobo Co., Ltd., thickness: 60 μm) as a heat contractible backing layer was superposed thereon, and these were laminated using a hand roller to obtain a laminate of heat contractible backing layer/elastic layer/rigid backing layer (1).

### Production Example 3-2

### Production of Heat Contractible Backing Layer/Elastic Layer/Rigid Backing Layer

An ester-based polymer was obtained from 100 parts by weight of “PLACCEL CD220PL” (trade name, produced by Daicel Chemical Industries, Ltd.) and 10 parts by weight of sebacic acid. A solution prepared by mixing 4 parts by weight of crosslinking agent (“Coronate L”, trade name, produced by Nippon Polyurethane Industry Co., Ltd.) per 100 parts by weight of the ester-based polymer was coated on the non-release-treated surface of a release sheet (“MRF38”, trade name, produced by Mitsubishi Polyester Film Corp., thickness: 38 μm) to have a dry thickness of 30 μm, a uniaxially stretched polyester film (“SPACECLEAN S5630”, trade name, produced by Toyobo Co., Ltd., thickness: 60 μm) as a heat contractible backing layer was superposed thereon, and these were laminated using a hand roller to obtain a laminate of heat contractible backing layer/elastic layer/rigid backing layer (2).

### Production Example 4-1

### Production of Supporting Tape

The pressure-sensitive adhesive layer obtained in Production Example 2-1 was laminated using a hand roller on the rigid backing layer side of the laminate of heat contractible backing layer/elastic layer/rigid backing layer (1) obtained in Production Example 3-1 to obtain supporting tape (1).

### Production Example 4-2

### Production of Supporting Tape

The active energy-curable pressure-sensitive adhesive layer obtained in Production Example 2-2 was laminated using a hand roller on the rigid backing layer side of the laminate of heat contractible backing layer/elastic layer/rigid backing layer (1) obtained in Production Example 3-1 to obtain supporting tape 2.

### Example 1

The heat contractible backing layer side of supporting tape (1) obtained in Production Example 4-1 was laminated using a hand roller to a polyolefin backing dicing tape (“DU-300”, trade name, ultraviolet ray-curable type, produced by Nitto Denko Corporation) and subsequently, the die attach film obtained in Production Example 1 was laminated using a hand roller on the pressure-sensitive adhesive layer side of supporting tape (1) to obtain a die attach film-provided dicing tape (1).

### Example 2

Die attach film-provided dicing tape (2) was obtained by the same operation as in Example 1 except for using supporting tape (2) obtained in Production Example 4-2 in place of supporting tape (1) obtained in Production Example 4-1.

### Example 3

Die attach film-provided dicing tape (3) was obtained by the same operation as in Example 1 except for using a vinyl chloride backing dicing tape (“V-8-S”, trade name, pressure-sensitive type, produced by Nitto Denko Corporation) in place of the polyolefin backing dicing tape (“DU-300”, trade name, ultraviolet ray-curable type, produced by Nitto Denko Corporation).

### Example 4

Die attach film-provided dicing tape (4) was obtained by the same operation as in Example 3 except for using supporting tape (2) obtained in Production Example 4-2 in place of supporting tape 1 obtained in Production Example 4-1.

### Example 5

The heat contractible backing layer side of the laminate (used as the supporting tape) of heat contractible backing layer/elastic layer/rigid backing layer (2) obtained in Production Example 3-2 was laminated by a hand roller to a polyolefin backing dicing tape (“DU-300”, trade name, ultraviolet ray-curable type, produced by Nitto Denko Corporation) and subsequently, the die attach film obtained in Production Example 1 was laminated by a hand roller to the rigid backing layer side (release-treated surface) to obtain a die attach film-provided dicing tape (5).

### Comparative Example 1

The die attach film obtained in Production Example 1 was laminated by a hand roller to a polyolefin backing dicing tape (“DU-300”, trade name, ultraviolet ray-curable type, produced by Nitto Denko Corporation) to obtain a die attach film-provided dicing tape (6).

### Comparative Example 2

Die attach film-provided dicing tape (7) was obtained by the same operation as in Comparative Example 1 except for using a vinyl chloride backing dicing tape (“V-8-S”, trade name, pressure-sensitive type, produced by Nitto Denko Corporation) in place of the polyolefin backing dicing tape (“DU-300”, trade name, ultraviolet ray-curable type, produced by Nitto Denko Corporation).

### Comparative Example 3

The backing layer side of a polyester tape (“No. 31K”, trade name, pressure-sensitive type, produced by Nitto Denko Corporation) was laminated using a hand roller to a polyolefin backing dicing tape (“DU-300”, trade name, ultraviolet ray-curable type, produced by Nitto Denko Corporation) and subsequently, the die attach film obtained in Production Example 1 was laminated using a hand roller on the pressure-sensitive adhesive layer side to obtain a die attach film-provided dicing tape (8).

Die attach film-provided dicing tapes (1) to (8) obtained in Examples and Comparative Examples were evaluated by the following methods.

### Evaluation of Picking

After laminating a back grind tape (“B Tape-RF 7213P”, trade name, pressure-sensitive type, produced by Nitto Denko Corporation) to a 8-inch silicon wafer, the silicon wafer was ground using a back grinder (“DFG8560”, trade name, manufactured by Disco Corp.) to a thickness of 30 μm.

Each of die attach film-provided dicing tapes (1) to (8) obtained in Examples and Comparative Examples was laminated to the ground surface above, and the wafer was cut into chips of 12 mm×12 mm by using a dicer (“DFD651”, trade name, manufactured by Disco Corp.). The cutting depth was set to a depth deep enough to cut 20 μm of the backing material of the dicing tape.

Subsequently, each of die attach film-provided dicing tapes (1), (2), (4) to (6) and (8) using an active energy ray-curable pressure-sensitive adhesive for the dicing tape and/or the supporting tape was irradiated with an ultraviolet ray from the dicing tape side to give an integrated light quantity of 300 mJ/cm² by using a high-pressure mercury lamp.

A chip was picked using a die bonder (“FED-1780”, trade name, manufactured by Shibaura Mechatronics Corporation). Incidentally, the pickup needle (350 R) was disposed at 5 portions of an area of 10 mm×10 mm, that is, four corners and a center, and picking was performed under the conditions of a picking height of 400 μm or 600 μm and a tact time (a time until the adsorption collet picked up a chip after contacting with the chip) of 0.2 seconds. Arbitrary 30 chips were pushed up by a pickup needle, and the number of chips that could be adsorbed by the adsorption collet was counted.

### Evaluation of Supporting Tape Peelability

With respect to 30 chips pushed up by the pickup needle, the chip was adsorbed from the chip side by using a adsorption collet (prototype) heated at 90° C., 110° C. or 130° C., and 0.2 seconds, 0.5 seconds, 1 second, 2 seconds or 3 seconds after the adsorption, air was blown against the chip by using an air gun. Whether the supporting tape peeled or not was observed, and the number of supporting tapes peeled was counted.

The results are shown together in the Table below.

TABLE 1

| | | | | Evaluation of Supporting Tape Peelability | | | | | | | | | | | | | | |
|---|---|---|---|---|---|---|---|---|---|---|---|---|---|---|---|---|---|---|
| | | Evaluation of Picking | | Temperature of Heater Collet: 90° C. | | | | | 110° C. | | | | | 130° C. | | | | |
| | | Pickup Height (μm) | | Time until Air is Blown after Picking (sec.) | | | | | | | | | | | | | | |
| | | 400 | 600 | 0.2 | 0.5 | 1 | 2 | 3 | 0.2 | 0.5 | 1 | 2 | 3 | 0.2 | 0.5 | 1 | 2 | 3 |
| Example | 1 | 30/30 | 30/30 | 0/30 | 0/30 | 9/30 | 20/30 | 30/30 | 0/30 | 0/30 | 27/30 | 30/30 | 30/30 | 0/30 | 0/30 | 30/30 | 30/30 | 30/30 |
| | 2 | 30/30 | 30/30 | 0/30 | 0/30 | 14/30 | 22/30 | 30/30 | 0/30 | 0/30 | 27/30 | 30/30 | 30/30 | 0/30 | 0/30 | 30/30 | 30/30 | 30/30 |
| | 3 | 23/30 | 30/30 | 0/30 | 0/30 | 6/30 | 20/30 | 30/30 | 0/30 | 0/30 | 25/30 | 30/30 | 30/30 | 0/30 | 0/30 | 30/30 | 30/30 | 30/30 |
| | 4 | 24/30 | 30/30 | 0/30 | 0/30 | 13/30 | 23/30 | 30/30 | 0/30 | 0/30 | 26/30 | 30/30 | 30/30 | 0/30 | 0/30 | 30/30 | 30/30 | 30/30 |
| | 5 | 30/30 | 30/30 | 0/30 | 0/30 | 18/30 | 30/30 | 30/30 | 0/30 | 0/30 | 30/30 | 30/30 | 30/30 | 0/30 | 0/30 | 30/30 | 30/30 | 30/30 |
| Compara- | 1 | 7/30 | 2/30 | 0/30 | 0/30 | 0/30 | 0/30 | 0/30 | 0/30 | 0/30 | 0/30 | 0/30 | 0/30 | 0/30 | 0/30 | 0/30 | 0/30 | 0/30 |
| tive | 2 | 0/30 | 3/30 | 0/30 | 0/30 | 0/30 | 0/30 | 0/30 | 0/30 | 0/30 | 0/30 | 0/30 | 0/30 | 0/30 | 0/30 | 0/30 | 0/30 | 0/30 |
| Example | 3 | 30/30 | 30/30 | 0/30 | 0/30 | 0/30 | 0/30 | 0/30 | 0/30 | 0/30 | 0/30 | 0/30 | 0/30 | 0/30 | 0/30 | 0/30 | 0/30 | 0/30 |

As seen from the results above, even an ultrathin chip could be picked at a high rate of success by using a pressure-sensitive adhesive tape in which a supporting tape is laminated between a dicing tape and a die attach film. On the other hand, in the die attach film-provided dicing tapes (6) and (7) in which a supporting tape is not laminated together, the rate of success of picking was extremely low as compared with the case of laminating a supporting tape together.

Also, in the case of using a supporting tape having self-rolling peelability, the supporting tape could be caused to undergo self-rolling by heating it using an adsorption collet (heater collet) equipped with a heating mechanism, and the supporting tape could be easily separated and collected by blowing air thereagainst. On the other hand, in the case of using a supporting tape having no self-rolling peelability [die attach film-provided dicing tape (8)], the supporting tape could not be removed even by blowing air thereagainst.

Furthermore, immediately after the picking, the supporting tape did not spontaneously fall in all cases irrespective of the temperature of the heater collet. This is considered to result because the supporting tape or die attach film has slight pressure-sensitive adhesiveness by itself. In other words, it was understood that the supporting tape is kept from falling associated with self-rolling within the pickup tact time (less than 1 second) and a fear of allowing a separated roll to fall on the wafer in the course of picking is eliminated. This reveals that continuous work can be performed by providing a separation/collection mechanism between the picking up and the die bonding.

While the present invention has been described in detail and with reference to specific embodiments thereof, it will be apparent to one skilled in the art that various changes and modifications can be made therein without departing from the scope thereof.

This application is based on Japanese patent application No. 2009-112002 filed May 1, 2009, the entire contents thereof being hereby incorporated by reference.

What is claimed is:

1. A die attach film-provided dicing tape, which comprises a dicing tape, a supporting tape and a die attach film laminated in this order, wherein the supporting tape is a tape having a self-rolling peelability.

2. The die attach film-provided dicing tape according to claim 1, wherein the dicing tape and the supporting tape are separable from each other at a picking after a dicing of an adherend.

3. The die attach film-provided dicing tape according to claim 1, wherein the supporting tape comprises a heat contractible backing layer, an elastic layer and a rigid backing layer laminated in this order from the dicing tape side.

4. The die attach film-provided dicing tape according to claim 1, wherein the supporting tape comprises a heat contractible backing layer, an elastic layer, a rigid backing layer and a pressure-sensitive adhesive layer (A) laminated in this order from the dicing tape side.

5. The die attach film-provided dicing tape according to claim 4, wherein the pressure-sensitive adhesive layer (A) is constituted of a pressure-sensitive adhesive or an active energy ray-curable pressure-sensitive adhesive.

6. The die attach film-provided dicing tape according to claim 1, wherein the dicing tape comprises a pressure-sensitive adhesive layer (B) and a backing layer laminated in this order from the supporting tape side.

7. The die attach film-provided dicing tape according to claim 6, wherein the pressure-sensitive adhesive layer (B) is constituted of a pressure-sensitive adhesive or an active energy ray-curable pressure-sensitive adhesive.

8. The die attach film-provided dicing tape according to claim 1, wherein the die attach film is constituted of a resin composition containing an epoxy resin.

9. A process for producing a semiconductor device, which comprises:
laminating a semiconductor wafer to a die attach film surface of the die attach film-provided dicing tape according to claim 1 to form a laminate structure comprising the dicing tape, the supporting tape, the die attach film and the semiconductor wafer laminated in this order; and
dicing said resulting laminate structure from the wafer side, followed by pushing it from the dicing tape side, thereby collecting a semiconductor chip possessing the supporting tape and the die attach film.

10. The process for producing a semiconductor device according to claim 9, which further comprises allowing the supporting tape to undergo self-rolling separation from said collected semiconductor chip possessing the supporting tape and the die attach film, thereby obtaining the semiconductor chip possessing the die attach film.

11. The process for producing a semiconductor device according to claim 10, wherein the semiconductor chip possessing the die attach film is obtained by collecting the semiconductor chip possessing the supporting tape and the die attach film by the use of a pickup adsorption collet equipped with a heating mechanism, followed by heating the supporting tape to undergo self-rolling separation from said collected semiconductor chip possessing the supporting tape and the die attach film.

12. The process for producing a semiconductor device according to claim 10, which further comprises bonding said obtained semiconductor chip possessing the die attach film to a die pad part.
